(19) United States
(12) Patent Application Publication
(10) Pub. No.: US 2026/0371625 A1
(43) Pub. Date: Nov. 19, 2026

(54) WIDE BANDGAP SEMICONDUCTOR DEVICE INCLUDING A BUFFER REGION

(71) Applicant: Infineon Technologies Austria AG, Villach (AT)

(72) Inventors: Christian Philipp Sandow, Haar (DE); Rudolf Elpelt, Erlangen (DE)

(21) Appl. No.: 19/676,953

(22) Filed: May 14, 2026

(30) Foreign Application Priority Data
May 19, 2025 (DE) 102025119399.1

(51) Int. Cl. H10D 8/60; H10D 8/01; H10D 62/832

(52) U.S. Cl. CPC H10D 8/60; H10D 8/051; H10D 62/8325

(57) ABSTRACT

A wide bandgap semiconductor device is described. The wide bandgap semiconductor device includes: a semiconductor substrate having a first surface and a second surface opposite to the first surface along a vertical direction; a first region of a first or second conductivity type; a drift region of a second conductivity type adjoining the first region; a highly doped second region adjoining the second surface; and a buffer region of the second conductivity type arranged between the drift region and the highly doped second region. A vertical profile of a doping concentration of the buffer region increases approximately exponentially toward the second surface in a first section and increases approximately linearly toward the second surface in a second section. The first section is arranged between the highly doped second region and the second section.

### TECHNICAL FIELD

The present disclosure is related to a wide bandgap semiconductor device, in particular to a wide bandgap semiconductor device including a buffer region.

### BACKGROUND

In the field of semiconductor devices, wide bandgap materials such as silicon carbide (SiC) and gallium nitride (GaN) have gained significant attention due to their superior electrical properties compared to traditional silicon-based semiconductors. These materials offer higher thermal conductivity, greater breakdown voltage, and faster switching speeds, making them ideal for high-power and high-frequency applications. Technology development of new generations of wide bandgap semiconductor devices, e.g. SiC power semiconductor devices, aims at improving electric device characteristics and reducing costs by shrinking device geometries.

One common approach in the design of wide bandgap semiconductor devices is the implementation of drift regions and buffer layers to control the flow of charge carriers and improve device efficiency. These regions are carefully engineered to balance the trade-offs between on-state resistance, Rₒₙ, and cosmic ray failure rate limitation, e.g. by optimizing the doping profiles and structural configurations of these devices.

There is a need for improved wide bandgap semiconductor devices with respect to the above challenges.

### SUMMARY

An example of the present disclosure relates to a wide bandgap semiconductor device. The wide bandgap semiconductor device includes a semiconductor substrate having a first surface and a second surface opposite to the first surface along a vertical direction. The wide bandgap semiconductor device further includes a first region of a first or second conductivity type. The wide bandgap semiconductor device further includes a drift region of a second conductivity type adjoining the first region. The wide bandgap semiconductor device further includes a highly doped second region adjoining the second surface. The wide bandgap semiconductor device further includes a buffer region of the second conductivity type arranged between the drift region and the highly doped second region. A vertical profile of a doping concentration of the buffer region is increasing approximately exponentially toward the second surface in a first section and is increasing approximately linearly toward the second surface in a second section. The first section is arranged between the highly doped second region and the second section.

Another example of the present disclosure relates to a method of manufacturing a wide bandgap semiconductor device. The method includes forming a first region of a first or second conductivity type in a semiconductor substrate having a first surface and a second surface opposite to the first surface along a vertical direction. The method further includes forming a drift region of a second conductivity type adjoining the first region. The method further includes forming a highly doped second region adjoining the second surface. The method further includes forming a buffer region of the second conductivity type arranged between the drift region and the highly doped second region. A vertical profile of a doping concentration of the buffer region is increasing approximately exponentially toward the second surface in a first section and is increasing approximately linearly toward the second surface in a second section. The first section is arranged between the highly doped second region and the second section.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 is a cross-section view for illustrating a wide bandgap semiconductor device including a buffer region with a first section and a second section.

FIG. 2 is a graph for illustrating an exemplary profile of doping concentration along a vertical direction of a wide bandgap semiconductor device including a buffer region.

FIG. 3 is a graph for illustrating vertical profiles of doping concentration within a drift region of the wide bandgap semiconductor device according to configuration examples.

FIG. 4 is a graph for illustrating vertical profiles of doping concentration within a buffer region of the wide bandgap semiconductor device according to configuration examples.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms "having", "containing", "including", "comprising" and the like are open, and the terms indicate the presence of stated structures, elements or features but do not preclude the presence of additional elements or features. The articles "a", "an" and "the" are intended to include the plural as well as the singular, unless the context clearly indicates otherwise.

The term "electrically connected" may describe a permanent low-resistive connection between electrically connected elements, for example a direct contact between the concerned elements or a low-resistive connection via a metal and/or heavily doped semiconductor material. The term "electrically coupled" may include that one or more intervening element(s) adapted for signal and/or power transmission may be connected between the electrically coupled elements, for example, elements that are controllable to temporarily provide a low-resistive connection in a first state and a high-resistive electric decoupling in a second state.

If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a ≤ y ≤ b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term "on" is not to be construed as meaning only "directly on". Rather, if one element is positioned "on" another element (e.g., a layer is "on" another layer or "on" a substrate), a further component (e.g., a further layer) may be positioned between the two elements (e.g., a further layer may be positioned between a layer and a substrate if the layer is "on" said substrate).

An example of a wide bandgap semiconductor device includes a semiconductor substrate having a first surface and a second surface opposite to the first surface along a vertical direction. The wide bandgap semiconductor device further includes a first region of a first or second conductivity type adjoining the first surface. The wide bandgap semiconductor device further includes a drift region of a second conductivity type adjoining the first region. The wide bandgap semiconductor device further includes a highly doped second region adjoining the second surface. The wide bandgap semiconductor device further includes a buffer region of the second conductivity type arranged between the drift region and the highly doped second region. A vertical profile of a doping concentration of the buffer region is increasing approximately exponentially toward the second surface in a first section and is increasing approximately linearly toward the second surface in a second section. The first section is arranged between the highly doped second region and the second section.

The wide bandgap semiconductor device may be part of an integrated circuit or may be a discrete semiconductor device or a semiconductor module, for example. The wide bandgap semiconductor device may be or a may include an insulated gate field effect transistor (IGFET) such as a metal oxide semiconductor field effect transistor (MOSFET), an insulated gate bipolar transistor (IGBT), a thyristor, a pn junction diode, or a Schottky junction diode, for example. The wide bandgap semiconductor device may be a vertical semiconductor device having a load current flow between the first surface and the second surface opposite to the first surface. The vertical power semiconductor device may be configured to conduct currents, e.g. continuous DC load current according to maximum ratings, of more than 1 A, or more than 10 A, or more than 30 A, or more than 50 A, or more than 75 A, or even more than 100 A, and may be further configured to block voltages between load electrodes, e.g. between collector and emitter of an IGBT, or between drain and source of a MOSFET, or between cathode and anode of a diode, in the range of several hundreds of up to several thousands of volts, e.g. 400 V, 650 V, 1.2 kV, 1.7 kV, 3.3 kV, 4.5 kV, 5.5 kV, 6 kV, 6.5 kV, 12 kV. The blocking voltage may correspond to a voltage class specified in a datasheet of the power semiconductor device, for example.

The wide bandgap semiconductor device may be based on a semiconductor body from a crystalline wide bandgap semiconductor material having a bandgap larger than the bandgap of silicon, i.e. larger than 1.12 eV. The wide bandgap semiconductor material may have a hexagonal or cubic crystal lattice and may be silicon carbide (SiC) or gallium nitride (GaN), by way of example. For example, the semiconductor material may be hexagonal 2H-SiC (SiC of the 2H polytype), hexagonal 6H-SiC, or rhombohedral 15R-SiC, or cubic 3C-SiC polytype. According to an example, the semiconductor material is silicon carbide of the 4H polytype (4H-SiC). The semiconductor body may include or consist of a semiconductor substrate having none, one or more than one semiconductor layers, e.g. epitaxially grown layers, thereon. The semiconductor layer(s) may be formed as part of a multi-epitaxial approach for forming a super junction structure, SJ structure, for example. During the multi-epitaxial approach for forming the SJ structure a masked p-implant and/or n-implant may be used between successive epi growths. The SJ structure may also be formed by deep trenches in one or more of the semiconductor layers followed by sidewall implants for defining the SJ structure. The SJ structure (e.g. p- and n-doped columns) may be separated from the buffer region by a region of low one-dimensional doping (no p- and n-doped columns) with typical drift zone concentrations as specified above. The distance of the SJ structure to the buffer region may be at least 1 µm, or 2 µm, or 5 µm, depending on blocking voltage to avoid electrical punch-through to the buffer. In some examples, the SJ structure may also adjoin the buffer region.

The first surface may be a front surface or a top surface of the semiconductor body, and the second surface may be a back surface or a rear surface of the semiconductor body, for ex-ample. The semiconductor body may be attached to a lead frame via the second surface, for example. Over the first surface of the semiconductor body, bond pads may be arranged and bond wires may be bonded on the bond pads, for example.

The first region may be of a first or second conductivity type, e.g. one of p- or n-type. For example, the first region may be of a first conductivity type adjoining at least partially the first surface. The first region may be or may include a body region of a MOSFET, or an anode region of a diode or a body region of an IGBT, for example. The first conductivity may be a p-type and the second conductivity type may be an n-type, e.g. for an n-channel MOSFET. However, the first conductivity type may also be an n-type and the second conductivity type may be a p-type, e.g. for a p-channel MOSFET. The first region may include a plurality of sub-regions, e.g. a p-doped body region and a p⁺-doped body contact region. The first region may be electrically connected to a first load electrode of the wide bandgap semiconductor device, e.g. via a contact plug or line on the first surface and/or via a groove contact. The first load electrode may be an emitter electrode of an IGBT, a source electrode of a MOSFET, or an anode of a diode, for example. The first load electrode may be part of a wiring area over the semiconductor body. The wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be arranged. Contact plug(s) or contact line(s) may be formed in openings of the interlayer dielectric structure to electrically connect parts, e.g. metal lines or contact areas, of different wiring levels to one another. The first load electrode may be formed by one or more elements of the wiring area.

The first region may form a pn junction with the drift region of the second conductivity type. The blocking voltage of the wide bandgap semiconductor device may be adjusted by an impurity or doping concentration and/or a vertical extent of a drift region in the semiconductor body. For wide bandgap power semiconductor devices based on SiC, a mean impurity concentration in the drift region may be between 5 x 10¹⁴ cm⁻³ and 1 x 10¹⁷ cm⁻³, for example in a range from 1 x 10¹⁵ cm⁻³ to 2 x 10¹⁶ cm⁻³. A vertical extent of the drift region may depend on voltage blocking requirements, e.g. a specified voltage class, of the wide bandgap semiconductor device. When operating the wide bandgap semiconductor device in voltage blocking mode, a space charge region may vertically extend partly or totally through the drift region depending on the blocking voltage applied to the wide bandgap semiconductor device. When operating the wide bandgap semiconductor device at or close to the specified maximum blocking voltage, the space charge region may reach or penetrate into a buffer region that is configured to prevent the space charge region from further reaching through the buffer to the buffer/substrate interface or to a contact of a second load electrode at the second surface. The second load electrode may be a collector electrode of an IGBT, or a drain electrode of a MOSFET, or a cathode of a diode, for example.

For example, the first region may also be of the second conductivity type adjoining at least partially the first surface. The area where the first region at least partially adjoins the first surface may be a Schottky contact area of a Schottky junction diode. The Schottky junction diode may further include a Schottky contact material as part of the first load electrode arranged on top the first region, for example.

For realizing a desired current carrying capacity, the wide bandgap semiconductor device may be designed by a plurality of parallel-connected wide bandgap semiconductor device cells. The parallel-connected wide bandgap semiconductor device cells may, for example, be wide bandgap semiconductor device cells formed in the shape of a strip or a strip segment. Of course, the wide bandgap semiconductor device cells can also have any other shape, e.g. circular, elliptical, polygonal such as hexagonal or octahedral. The wide bandgap semiconductor device cells may be arranged in an active area of the semiconductor body. The active area may be an area where an emitter region of an IGBT, or a source region of a MOSFET or anode region of a diode at the first surface and a collector region of an IGBT, or a drain region of a MOSFET or a cathode region of a diode are arranged opposite to one another along the vertical direction. In the active area, a load current may enter or exit the semiconductor body of the wide bandgap semiconductor device, e.g. via contact plugs on the first surface of the semiconductor body. The wide bandgap semiconductor device may further include an edge termination area that may include a termination structure. In a blocking mode or in a reverse biased mode of the wide bandgap semiconductor device, the blocking voltage between the active area and a field-free region laterally drops across the termination structure. The termination structure may have a higher or a slightly lower voltage blocking capability than the active area. The termination structure may include a junction termination extension (JTE) with or without a variation of lateral doping (VLD), one or more laterally separated guard rings, or any combination thereof, for example.

The highly doped second region adjoining the second surface may be a collector region, e.g. a highly doped rear side emitter region, of the first conductivity type in case the wide bandgap semiconductor device is an IGBT. The highly doped second region adjoining the second surface may also be a drain region of the second conductivity type in case the wide bandgap semiconductor device is an IGFET such as a MOSFET. The highly doped second region adjoining the second surface may also be a cathode region in case the wide bandgap semiconductor device is a diode. The highly doped semiconductor region may also be configured, e.g. by doping amount and material, for an ohmic contact to a second load electrode, e.g. a metallization layer, and/or to ensure safe handling during manufacturing processes by providing a thickness of the semiconductor body sufficient for mechanical stability.

The buffer region of the second conductivity type including the first and second sections aims at preventing an electric field from reaching to the substrate/buffer region interface, or even from reaching deep into the buffer. The doping profiles may be shaped by process technology, e.g. by thermal diffusion processes of dopants or supply of precursor gases. The approximately exponential increase of the doping profile in the first section of the buffer region may be manufactured, for example, by a fast reduction of supply of dopants from a high doping level down to lower doping level during growth or deposition of the first section. For example, a local deviation, e.g. caused by semiconductor processing for approximating an exponential increase of a doping profile, from an ideal exponential increase of the approximately exponential increase of the doping profile in the first section of the buffer region may be smaller than 50%, or smaller than 30%, or even smaller than 15%. The same likewise applies to the approximately linear increase in the second section.

The configuration examples of the wide bandgap semiconductor devices described herein may achieve an improved cosmic ray ruggedness and softness during turn-off of the devices via the vertical profile of doping concentration in the buffer region.

For example, the vertical profile of a doping concentration of the buffer region may further include at least one step in a third section. The third section may be arranged between the highly doped second region and the first section. The introduction of the third section in the doping profile signifies a discrete change in doping concentration, which can influence the electrical characteristics of the buffer region and can on the one hand mitigate the propagation of crystal defects from the substrate into the drift layer. On the other hand the third section can mitigate growth of stacking faults during bipolar operation of the device by suppressing the diffusion of minority carriers from the drift region to the substrate/buffer interface.

For example, a step of the at least one step located closest to the highly doped second region may have a portion or step tread with a doping concentration in a range from 5 x 10¹⁷ cm⁻³ to 2 x 10¹⁹ cm⁻³, or from 1 x 10¹⁸ cm⁻³ to 5 x 10¹⁸ cm⁻³. The portion of the step of the vertical profile of the doping concentration of the buffer region may be a step tread having constant or almost const doping concentration, for example. The step may further include a step riser representing a sharp increase of the doping concentration of the buffer region. By defining the doping concentration range, the buffer region can effectively manage the electric field distribution and reduce the likelihood of device failure due to high electric fields caused by, for example, cosmic ray events. This feature also contributes to the reliability of the semiconductor device.

For example, a vertical profile of the doping concentration of the drift region may be constant in at least one section and/or may be monotonically increasing toward the second surface in at least one other section. The monotonically increasing doping concentration toward the second surface may allow for a gradient in electrical properties, which can be tailored to enhance the device's on-state resistance and switching softness.

For example, the vertical profile of a doping concentration of the drift region may increase, along a vertical extent of the drift region, by a factor ranging from 2 to 10.

For example, the drift region may adjoin the second section of the buffer region along the vertical direction. The second section of the buffer region may further adjoin the first section of the buffer region along the vertical direction. This arrangement suggests that the drift region is in close proximity to the linearly increasing doping concentration section of the buffer region, potentially affecting the electric field distribution and charge carrier movement within the device. Furthermore, above feature describes the second section of the buffer region as adjoining the first section along the vertical direction, indicating a continuous transition between the exponentially increasing doping profile and the linearly increasing doping profile. This continuity in the doping concentration profile may improve the softness via the linearly increasing doping concentration section of the buffer region and may further contribute to an improved cosmic ray ruggedness via the exponentially increasing doping profile by increasing a second breakdown voltage in the breakdown current/voltage characteristic between the load electrodes.

For example, a vertical extent of the first section of the buffer region may have a value in a range from 5 % to 50 % of a vertical extent of the drift region.

For example, a vertical extent of the first section of the buffer region may have a value in a range from 1 µm to 15 µm.

For example, a vertical extent of the second section of the buffer region may have a value in a range from 5 % to 50 % of a vertical extent of the drift region.

For example, a vertical extent of the second section of the buffer region may have a value in a range from 1 µm to 10 µm. For example, the vertical extent of the first section may be larger than the vertical extent of the second section. For improving the electric field distribution, the first section may be more than 25 % larger and less than 500 % larger than the second section, or the first section may be more than 30 % larger and less than 300 % larger than the second section, or the first section may be more than 50 % larger and less than 300 % larger than the second section, or the first section may be more than 50 % larger and less than 200 % larger than the second section.

For example, the vertical profile of a doping concentration of the buffer region may be increasing approximately exponentially by a factor ranging from 3 to 100, or from 5 to 50, in the first section toward the second surface.

For example, a maximum doping concentration of the buffer region in the first section may have a value in a range from 3 x 10¹⁷ cm⁻³ to 5 x 10¹⁸ cm⁻³, or in a range from 5 x 10¹⁷ cm⁻³ to 3 x 10¹⁸ cm⁻³.

For example, the vertical profile of a doping concentration of the buffer region may be increasing approximately linearly by a factor ranging from 2 to 20 in the second section toward the second surface.

For example, a maximum doping concentration of the buffer region in the second section may have a value in a range from 4 x 10¹⁶ cm⁻³ to 2 x 10¹⁷ cm⁻³.

For example, the wide bandgap semiconductor device may further include a first load electrode electrically connected to the first region via the first surface. The wide bandgap semiconductor device may further include a second load electrode electrically connected to the highly doped second region via the second surface. A vertical extent of the buffer region in units of µm may be in a range from 50% to 150% of three times a value of Vbr in units of kV, Vbr being an electric breakdown voltage between the first load electrode and the second load electrode.

For an electric breakdown voltage Vbr of 1kV, the buffer region may have a vertical extent ranging from 0.5 µm to 4.5 µm, for example. The first electrode load electrode may be an emitter electrode of an IGBT, a source electrode of a MOSFET, or an anode of a diode, for example. The first load electrode may be part of a wiring area over the semiconductor body. The second load electrode may be a collector electrode of an IGBT, a drain electrode of a MOSFET, or a cathode of a diode, for example.

The examples and features described above and below may be combined.

Functional and structural details (e.g. materials, dimensions) described with respect to the examples above shall likewise apply to the examples illustrated in the figures and described with reference to manufacturing methods further below.

A method of manufacturing a wide bandgap semiconductor device includes forming a first region of a first or second conductivity type in a semiconductor substrate having a first surface and a second surface opposite to the first surface along a vertical direction. The method further includes forming a drift region of a second conductivity type adjoining the first region. The method further includes forming a highly doped second region adjoining the second surface. The method further includes forming a buffer region of the second conductivity type arranged between the drift region and the highly doped second region. A vertical profile of a doping concentration of the buffer region is increasing approximately exponentially toward the second surface in a first section and is increasing approximately linearly toward the second surface in a second section. The first section is arranged between the highly doped second region and the second section.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub–acts, -functions, -processes, -operations or –steps, respectively. Such sub acts may be included and part of the disclosure of this single act unless explicitly excluded. For example, an exemplary sequence of the above features may start with forming the highly doped second region, e.g. as part of a base substrate, followed by forming the buffer layer and the drift region, e.g. by one or more layer deposition processes. The first region may be formed after forming the buffer layer and after forming the drift region, for example.

For example, forming the first section of the buffer region may include a reduction of supply of dopants during in-situ doping of deposited SiC over a SiC base substrate. This may contribute to setting the vertical profile of the doping concentration of the buffer region increasing approximately exponentially toward the second surface in the first section.

For example, the method may further include forming a third section of the buffer region. The vertical profile of a doping concentration of the buffer region may further include at least one step in the third section. The third section may be arranged between the highly doped second region and the first section. The introduction of the third section in the doping profile signifies a discrete change in doping concentration, which can influence the electrical characteristics of the buffer region and can on the one hand mitigate the propagation of crystal defects from the substrate into the drift layer. On the other hand the third section can mitigate growth of stacking faults during bipolar operation of the device by suppressing the diffusion of minority carriers from the drift region to the substrate/buffer interface..

For example, the vertical profile of a doping concentration of the buffer region may be set to increase approximately exponentially by a factor ranging from 3 to 100 in the first section toward the second surface.

For example, the vertical profile of a doping concentration of the buffer region may be set to increase approximately linearly by a factor ranging from 2 to 20 in the second section toward the second surface.

More details and aspects are mentioned in connection with the examples described above or below. Processing a wide bandgap semiconductor wafer may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

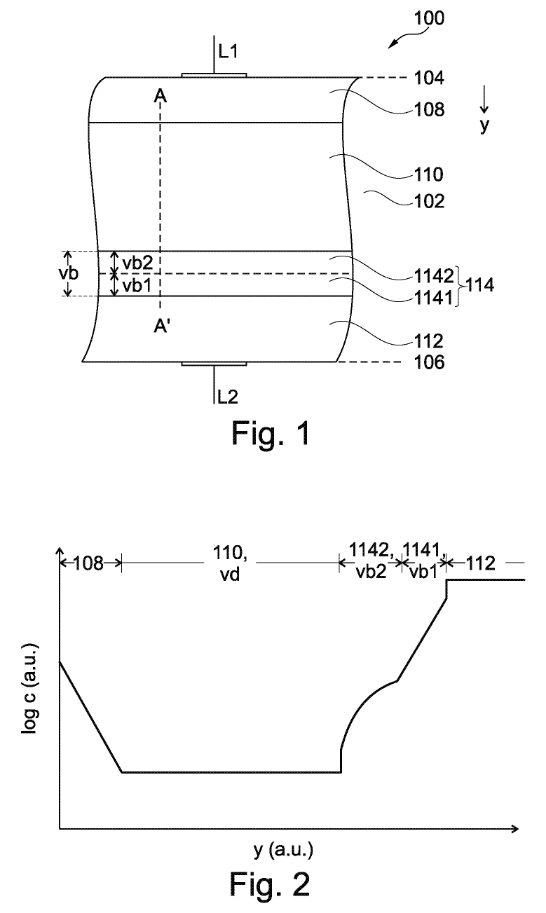

FIG. 1 is a cross-sectional view illustrating a configuration example of a wide bandgap semiconductor device 100. The wide bandgap semiconductor device 100 includes a semiconductor substrate 102, which has a first surface 104 and a second surface 106 opposite to the first surface 104 along a vertical direction y. A first region 108 of the wide bandgap semiconductor device 100 is of either a first or second conductivity type. For example, the first region 108 may be of the first conductivity type adjoining at least partially the first surface 104. The first region may be or may include a body region of a MOSFET, or an anode region of a diode or a body of an IGBT, for example. For a wide bandgap semiconductor device 100 implemented as a Schottky junction diode, the first region 108 may also be of the second conductivity type adjoining at least partially the first surface 104. The first region 108 may also include a plurality of sub-regions, e.g. a p-doped body region and a p⁺-doped body contact region. It is to be noted that the FIG. 1 illustrates only a part of the wide bandgap semiconductor device 100. For example, in other parts not illustrated in FIG. 1, the first region may be replaced by a region of opposite conductivity type. For example, FIG. 1 may illustrate, in a simplified manner, the first region 108 including a p-doped body region and a p⁺-doped body contact region as sub-regions of a MOSFET or IGBT. In other parts not illustrated in FIG. 1, an n⁺-doped source or emitter region of the MOSFET or IGBT may adjoin the first surface 104, for example.

Adjacent to the first region 108 is a drift region 110, which is of the second conductivity type. The highly doped second region 112 is positioned adjoining the second surface 106.

Between the drift region 110 and the highly doped second region 112 lies a buffer region 114, which is also of the second conductivity type. The buffer region 114 is divided into first and second sections based on the vertical profile of its doping concentration. The first section 1141 of the buffer region 114 is situated between the highly doped second region 112 and the second section 1142. In the first section 1141, the doping concentration increases approximately exponentially toward the second surface 106. The second section 1142, which is arranged between the first section 1141 and the drift region 110, exhibits a doping concentration that increases approximately linearly toward the second surface 106.

The wide bandgap semiconductor device 100 further includes a first load electrode L1 on the first region 108, and a second load electrode L2 electrically connected to the highly doped second region 112 via the second surface 106. For example, a vertical extent vb of the buffer region 114 in units of µm may be in a range from 50% to 150% of three times the value of Vbr in units of kV, Vbr being the electric breakdown voltage between the first load electrode L1 and the second load electrode L2.

A vertical extent vb1 of the first section 1141 of the buffer region 114 may have a value in a range from 5 % to 50 % of the vertical extent vd of the drift region 110. Additionally, the vertical extent vb1 of the first section 1141 of the buffer region 114 may have a value in a range from 1 µm to 15 µm for a 3 kV voltage class device or may have a value in a range from 0.5 µm to 5 µm for a 1.2 kV voltage class device. A vertical extent vb2 of the second section 1142 of the buffer region 114 may have a value in a range from 5 % to 50 % of the vertical extent vd of the drift region 110, and a value in a range from 1 µm to 10 µm.

The vertical profile of the doping concentration c of the buffer region 114 may increase approximately exponentially by a factor ranging from 3 to 100 in the first section 1141 toward the second surface 106. The maximum doping concentration c of the buffer region 114 in the first section 1141 may have value in a range from 3 x 10¹⁷ cm⁻³ to 5 x 10¹⁸ cm⁻³. The vertical profile of the doping concentration c of the buffer region 114 may increase approximately linearly by a factor ranging from 2 to 20 in the second section 1142 toward the second surface 106. The maximum doping concentration c of the buffer region 114 in the second section 1142 may have a value in a range from 4 x 10¹⁶ cm⁻³ to 2 x 10¹⁷ cm⁻³.

The above values and ranges provided with reference to FIG. 1 are merely examples and are not restrictive and can be combined with each other.

FIG. 2 is a graph for illustrating an exemplary vertical profile of doping concentration c in a wide bandgap semiconductor device along the vertical direction y. For example, the profile may be taken along line A-A’ of FIG. 1. The doping concentration is plotted in arbitrary units on a logarithmic scale along the y-axis, while the vertical direction y is represented on the x-axis in arbitrary units. The first region 108, which is of either the first or second conductivity type, is adjacent to the first surface 104 in the illustrated part of the wide bandgap semiconductor device 100 and the vertical profile of doping concentration c of the first region 108 decreases, as a non-limiting example for illustration purposes, approximately exponentially toward the second surface and adjoins the drift region 110, e.g. via a pn junction for a MOSFET, IGBT or pn junction diode. Of course, the first region 108 may have other profile shapes. The first region 108 may also include sub-regions having different doping profiles depending on the layout of the device. The drift region 110, which is of the second conductivity type, adjoins the first region 108 and extends vertically with a vertical extent vd.

The buffer region 114 is situated between the drift region 110 and the highly doped second region 112. The highly doped second region 112 may be or may be part of a highly doped base substrate, for example. The buffer region 114 is divided into two sections based on the vertical profile of the doping concentration. The first section 1141 of the buffer region 114 exhibits an approximately exponential increase in doping concentration toward the second surface 106. This section 1141 is positioned between the highly doped second region 112 and the second section 1142 and has a vertical extent vb1.

The second section 1142 of the buffer region 114 shows an approximately linear increase in doping concentration toward the second surface 106. This section 1142 is arranged between the first section 1141 and the drift region 110 along the vertical direction y and has a vertical extent vb2. A course of a vertical profile of a doping concentration in the drift region 110 differs from a course of a vertical profile of the doping concentration in the second section 1142 of the buffer region 114.

The exemplary vertical profile of the doping concentration in the drift region 110 is shown to be constant. Other examples may also have drift regions with varying doping concentration, e.g. constant in at least one section and monotonically increasing toward the second surface 106 in another section.

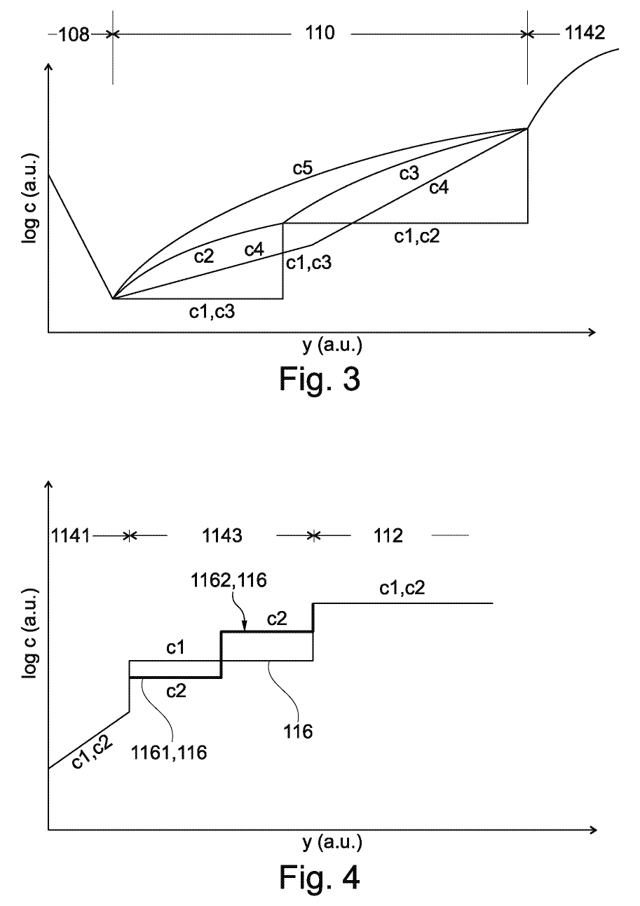

FIG. 3 illustrates vertical profiles of doping concentration c within the drift region 110 of wide bandgap semiconductor devices 100 according to configuration examples. The doping concentration is plotted in arbitrary units on a logarithmic scale along the y-axis, while the vertical direction y is represented on the x-axis in arbitrary units.

The drift region 110 adjoins the first region 108 and extends vertically along the y-axis to the second section 1142 of the buffer region 114.

The exemplary profiles of the doping concentration c in the drift region 110 are divided into two sections for exemplary profiles c1, c2, c3, and c4. Exemplary profile of doping concentration c1 illustrates two sections having constant but different doping concentrations that merge via a step with the section toward the second surface having the higher doping concentration. Exemplary profile of doping concentration c2 illustrates two sections having a first section with a doping concentration that is monotonically increasing toward the buffer layer 114. In the direction toward the buffer layer 114, the first section of the profile c2 turns into a second section having a constant doping concentration. Exemplary profile of doping concentration c3 illustrates two sections having a first section with a doping concentration that is constant. In the direction toward the buffer layer 114, the first section of the profile c3 turns into a second section having a doping concentration that is monotonically increasing toward the buffer layer 114. Exemplary profile of doping concentration c4 illustrates two sections with a doping concentration that is monotonically increasing toward the buffer layer 114 in each section and having a gradient of the monotonic increase that is larger in the section closer to the buffer layer 114. Exemplary profile of doping concentration c5 is based on a single section having a doping concentration that is monotonically increasing toward the buffer layer 114. The number and profiles of the sections may be varied, combined and adapted to the specific requirements of the device.

FIG. 4 illustrates vertical profiles of doping concentration c within the buffer region 114 of wide bandgap semiconductor devices 100 according to configuration examples. The doping concentration is plotted on a logarithmic scale along the y-axis, while the vertical direction y is represented on the x-axis in arbitrary units.

In the first section 1141 of the buffer region 114, the doping concentration increases approximately exponentially toward the second surface. This exponential increase is depicted by the upward slope in the graph, indicating a significant change in doping concentration over a relatively short vertical distance.

Adjacent to first section 1141 is a third section 1143 of the buffer region 114 that is arranged between the highly doped second region 112 and the first section 1141.

Exemplary profile of doping concentration c1 in the third section 1143 represents a step 116 with a step riser and a step tread that is closest to the highly doped second region 112. Exemplary profile of doping concentration c2 in the third section 1143 includes two sub-sections. A step 1161 in a first sub-section has a step tread with a lower doping concentration than a step tread of a step 1162 that is located closer to the highly doped second region 112. The number and doping concentration of the steps may be varied for adapting the electric field characteristics to the specific requirements of the device.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A wide bandgap semiconductor device, comprising:
a semiconductor substrate having a first surface and a second surface opposite to the first surface along a vertical direction;
a first region of a first or second conductivity type;
a drift region of a second conductivity type adjoining the first region;
a highly doped second region adjoining the second surface; and
a buffer region of the second conductivity type arranged between the drift region and the highly doped second region,
wherein a vertical profile of a doping concentration of the buffer region increases approximately exponentially toward the second surface in a first section, and is increases approximately linearly toward the second surface in a second section, the first section being arranged between the highly doped second region and the second section.

2. The wide bandgap semiconductor device of claim 1, wherein the vertical profile of the doping concentration of the buffer region further comprises at least one step in a third section, the third section being arranged between the highly doped second region and the first section.

3. The wide bandgap semiconductor device of claim 2, wherein a step of the at least one step located closest to the highly doped second region has a portion with a doping concentration in a range from 5 x 10¹⁷ cm⁻³ to 2 x 10¹⁹ cm⁻³.

4. The wide bandgap semiconductor device of claim 1, wherein a vertical profile of a doping concentration of the drift region is constant in at least one section and/or monotonically increases toward the second surface in at least one other section.

5. The wide bandgap semiconductor device of claim 4, wherein the vertical profile of the doping concentration of the drift region increases, along a vertical extent of the drift region, by a factor ranging from 2 to 10.

6. The wide bandgap semiconductor device of claim 1, wherein the drift region adjoins the second section of the buffer region along the vertical direction, and wherein the second section of the buffer region further adjoins the first section of the buffer region along the vertical direction.

7. The wide bandgap semiconductor device of claim 1, wherein a vertical extent of the first section of the buffer region has a value in a range from 5 % to 50 % of a vertical extent of the drift region.

8. The wide bandgap semiconductor device of claim 1, wherein a vertical extent of the first section of the buffer region has a value in a range from 1 µm to 15 µm.

9. The wide bandgap semiconductor device of claim 1, wherein a vertical extent of the second section of the buffer region has a value in a range from 5 % to 50 % of a vertical extent of the drift region.

10. The wide bandgap semiconductor device of claim 1, wherein a vertical extent of the second section of the buffer region has a value in a range from 1 µm to 10 µm.

11. The wide bandgap semiconductor device of claim 1, wherein the vertical profile of the doping concentration of the buffer region increases approximately exponentially by a factor ranging from 3 to 100 in the first section toward the second surface.

12. The wide bandgap semiconductor device of claim 11, wherein a maximum doping concentration of the buffer region in the first section has a value in a range from 3 x 10¹⁷ cm⁻³ to 5 x 10¹⁸ cm⁻³.

13. The wide bandgap semiconductor device of claim 1, wherein the vertical profile of the doping concentration of the buffer region increases approximately linearly by a factor ranging from 2 to 20 in the second section toward the second surface.

14. The wide bandgap semiconductor device of claim 1, wherein a maximum doping concentration of the buffer region in the second section has a value in a range from 4 x 10¹⁶ cm⁻³ to 2x 10¹⁷ cm⁻³.

15. The wide bandgap semiconductor device of claim 1, further comprising:
a first load electrode electrically connected to the first region via the first surface; and
a second load electrode electrically connected to the highly doped second region via the second surface,
wherein a vertical extent of the buffer region in units of µm is in a range from 50% to 150% of three times a value of Vbr in units of kV, Vbr being an electric breakdown voltage between the first load electrode and the second load electrode.

16. A method of manufacturing a wide bandgap semiconductor device, the method comprising:
forming a first region of a first or second conductivity type in a semiconductor substrate having a first surface and a second surface opposite to the first surface along a vertical direction;
forming a drift region of a second conductivity type adjoining the first region;
forming a highly doped second region adjoining the second surface; and
forming a buffer region of the second conductivity type arranged between the drift region and the highly doped second region,
wherein a vertical profile of a doping concentration of the buffer region increases approximately exponentially toward the second surface in a first section and increases approximately linearly toward the second surface in a second section, the first section being arranged between the highly doped second region and the second section.

17. The method of claim 16, wherein forming the first section of the buffer region includes a reduction of supply of dopants during in-situ doping of deposited SiC over a SiC base substrate.

18. The method of claim 16, further comprising:
forming a third section of the buffer region,
wherein the vertical profile of the doping concentration of the buffer region further comprises at least one step in the third section, the third section being arranged between the highly doped second region and the first section.

19. The method of claim 16, wherein the vertical profile of the doping concentration of the buffer region is set to increase approximately exponentially by a factor ranging from 3 to 100 in the first section toward the second surface.

20. The method of claim 16, wherein the vertical profile of the doping concentration of the buffer region is set to increase approximately linearly by a factor ranging from 2 to 20 in the second section toward the second surface.
